(19) United States
(12) Patent Application Publication
(10) Pub. No.: US 2024/0112911 A1
(43) Pub. Date: Apr. 4, 2024

(54) LASER CRYSTALLIZATION APPARATUS AND LASER CRYSTALLIZATION METHOD

(71) Applicant: Samsung Display Co., LTD., Yongin-si (KR)

(72) Inventors: Heegwan RYU, Yongin-si (KR); Jaesung GU, Yongin-si (KR); Deokjae KIM, Yongin-si (KR); Dongchan SEO, Yongin-si (KR); Younghoon OH, Yongin-si (KR); Yujin OH, Yongin-si (KR); Eunji LIM, Yongin-si (KR)

(21) Appl. No.: 18/199,578

(22) Filed: May 19, 2023

(30) Foreign Application Priority Data
Sep. 30, 2022 (KR) 10-2022-0125223

(51) Int. Cl. H01L 21/02; B23K 26/0622; H01L 21/67

(52) U.S. Cl. CPC H01L 21/02686; B23K 26/0622; H01L 21/67115; H01L 21/67253; H01L 2021/775

(57) ABSTRACT

A laser crystallization apparatus includes: a plurality of laser generators which generates an incident laser beam; an optical system which optically converts the incident laser beam to an output laser beam; a process chamber in which a thin film formed on a substrate is crystallized by the output laser beam radiated thereto; a first monitoring device which detects a synthesized pulse of the output laser beam; a second monitoring device which detects individual pulses of the incident laser beam; and a controller which controls oscillation times of the plurality of laser generators. The controller generates a plurality of synthesized pulses by combining the individual pulses of the incident laser beam, and derives an optimal synthesized pulse from the plurality of synthesized pulses.

This application claims priority to Korean Patent Application No. 10-2022-0125223, filed on Sep. 30, 2022, and all the benefits accruing therefrom under 35 U.S.C. § 119, the content of which in its entirety is herein incorporated by reference.

### BACKGROUND

### 1. Field

The disclosure relates to a laser crystallization apparatus and a laser crystallization method using the laser crystallization apparatus. Specifically, the disclosure relates to a laser crystallization apparatus and method capable of pre-managing a crystallization quality using the laser crystallization apparatus.

### 2. Description of the Related Art

In general, a method for crystallizing an amorphous silicon layer into a polycrystalline silicon layer includes a solid phase crystallization (SPC) method, a metal induced crystallization (MIC) method, a metal induced lateral crystallization (MILC) method, an excimer laser annealing (ELA) method, or the like.

In a manufacturing process of an organic light emitting diode display (OLED) or a liquid crystal display (LCD), the excimer laser annealing (ELA) method is typically used to crystallize amorphous silicon into polycrystalline silicon using a laser beam.

A laser crystallization apparatus used in the excimer laser annealing (ELA) method may use a pulse laser. When crystallization of the amorphous silicon is performed using the pulse laser, a degree of crystallization of the polycrystalline silicon may be affected by a pulse shape of the laser.

### SUMMARY

Embodiments are to pre-manage crystallization quality when crystallization is performed using a laser. In particular, the embodiments provide an apparatus and method in which, when crystallization of an amorphous silicon layer using a plurality of pulse lasers is performed, a synthesized pulse shape (a composite pulse shape) that provides the desired crystallization is derived and a condition of an incident laser beam is controlled in a way such that an output laser beam becomes substantially the same as an optimal synthesized pulse.

A laser crystallization apparatus according to an embodiment includes: a plurality of laser generators which generates an incident laser beam; an optical system which optically converts the incident laser beam to an output laser beam; a process chamber in which a thin film formed on a substrate is crystallized by the output laser beam radiated thereto; a first monitoring device which detects a synthesized pulse of the output laser beam; a second monitoring device which detects individual pulses of the incident laser beam; and a controller which controls oscillation times of the plurality of laser generators. In such an embodiment, the controller generates a plurality of synthesized pulses by combining the individual pulses of the incident laser beam, and derives an optimal synthesized pulse from the plurality of synthesized pulses.

In an embodiment, the controller may control the oscillation times of the laser generators in a way such that the synthesized pulse of the output laser beam is substantially the same as the optimal synthesized pulse.

In an embodiment, the controller may generate each of the plurality of synthesized pulses by applying a time delay to each of the individual pulses.

In an embodiment, the oscillation times of the plurality of laser generators may be determined based on time delays of the individual pulses constituting the optimal synthesized pulse.

In an embodiment, the optimal synthesized pulse may be derived by calculating a score based on a pulse management factor extracted from the synthesized pulses. In an embodiment, for example, the optimal synthesized pulse may be derived by calculating the score based on at least one selected from a first peak intensity, a first peak smoothness up to a first peak, a second peak intensity, an intensity of a valley between the first peak and a second peak, and a full width at half maximum (FWHM) which is a time width at a half height of the first peak. In an embodiment, the first peak intensity, the first peak smoothness, the second peak intensity, the intensity of the valley, and the full width at half maximum may be included in the pulse management factor.

In an embodiment, a weight according to a degree of crystallization of the thin film may be given to the pulse management factor to calculate the score.

In an embodiment, the degree of crystallization of the thin film may be determined based on at least one selected from a surface roughness, a crystal size, and mura visibility of the thin film.

In an embodiment, the controller may compare a pulse management factor of the synthesized pulse of the output laser beam with a pulse management factor of the optimal synthesized pulse, and may generate an abnormality detection signal when a comparison result is out of a predetermined range.

In an embodiment, the controller may generate a synthesized pulse of the incident laser beam and derive the optimal synthesized pulse through a machine learning.

In an embodiment, the machine learning may use at least one selected from Q-learning, Deep Q-learning, Double Deep Q-learning, a decision tree, a neural network, a support vector machine (SVM), a genetic algorithm, and Bayesian optimization.

In an embodiment, the laser crystallization apparatus may further include a third monitoring device which detects shapes of the individual pulses of the incident laser beam at an arbitrary point within the optical system.

A laser crystallization apparatus according to an embodiment includes: a plurality of laser generators which generate a plurality of individual laser beams; an optical system which optically converts the individual laser beams to a synthesized laser beam; a process chamber in which a thin film formed on a substrate is crystallized by the synthesized laser beam radiated thereto; a first monitoring device which detects a pulse of each of the individual laser beams and a pulse of the synthesized laser beam; and a controller which controls oscillation times of the plurality of laser generators. In such an embodiment, the controller derives an optimal synthesized pulse among a plurality of synthesized pulses obtained by combining pulses of the individual laser beams detected by the first monitoring device.

In an embodiment, the controller may control the oscillation times of the plurality of laser generators in a way such that the pulse of the synthesized laser beam is substantially the same as the optimal synthesized pulse.

In an embodiment, the first monitoring device may detect a pulse of an individual laser beam output from one of the plurality of laser generators through the optical system.

In an embodiment, the controller may compare a pulse management factor of the pulse of the synthesized laser beam with a pulse management factor of the optimal synthesized pulse, and may generate an abnormality detection signal when a comparison result is out of a predetermined range.

A laser crystallization method in which a synthesized laser beam obtained by optically converting a plurality of laser beams is radiated to crystallize a thin film according to an embodiment includes: generating a plurality of laser beams from a plurality of laser generators; monitoring individual pulses of the plurality of laser beams; generating a plurality of synthesized pulses by applying a time delay to each of the individual pulses; deriving an optimal synthesized pulse from the plurality of synthesized pulses; and comparing the optimal synthesized pulse with a pulse of the synthesized laser beam.

In an embodiment, the monitoring of the individual pulses of the plurality of laser beams may include monitoring an individual pulse of a laser beam after the laser beam generated by only one laser generator among the plurality of laser generators passes through an optical system.

In an embodiment, the deriving of the optimal synthesized pulse may include deriving the optimal synthesized pulse based on at least one selected from a first peak intensity, a first peak smoothness up to a first peak, a second peak intensity, an intensity of a valley between the first peak and a second peak, and a full width at half maximum which is a time width at a half height of the first peak. In such an embodiment, the first peak intensity, the first peak smoothness, the second peak intensity, the intensity of the valley, and the full width at half maximum may be included in a pulse management factor.

In an embodiment, the laser crystallization method may further include generating an abnormality detection signal when a result of comparing the optimal synthesized pulse with the pulse of the synthesized laser beam is out of a predetermined range.

In an embodiment, the laser crystallization method may further include controlling oscillation times of the plurality of laser generators based on time delays of the individual pulses constituting the optimal synthesized pulse.

According to embodiments, an oscillation condition of an individual incident laser beam may be controlled to derive an optimal output laser beam for high-quality thin film crystallization so that quality of thin film crystallization is managed in advance. In such embodiments, in a crystallization process using the laser generators, equipment conditions (facility conditions) may be managed and controlled in advance so that pulses of individual laser beams are monitored and an optimal synthesized laser pulse of the synthesized laser beam combining the pulses of the individual laser beams is derived.

In such embodiments, by monitoring the synthesized pulse of the output laser beam in real time, it is possible to check whether equipment is abnormal, to prevent a defect due to equipment abnormality in advance, and to enable high-quality thin film crystallization.

### BRIEF DESCRIPTION OF THE DRAWINGS

FIG. 1 is a view schematically illustrating a laser crystallization apparatus according to an embodiment.

FIG. 2 is a view schematically illustrating a laser crystallization apparatus according to an embodiment.

FIG. 3 is a flowchart of a real-time monitoring method of the laser crystallization apparatus according to an embodiment.

FIG. 4 is a view illustrating a configuration of a controller according to an embodiment.

FIG. 5 is a graph illustrating a synthesized pulse shape according to an embodiment.

FIGS. 6A and 6B are views comparing an actual measurement result with a simulation result according to an embodiment.

FIGS. 7A and 7B are views comparing an actual measurement result with a simulation result according to an embodiment.

FIG. 8 is a view schematically illustrating a laser crystallization apparatus according to an embodiment.

FIGS. 9A and 9B are views regarding degrees of crystallization before and after optimization control for the synthesized pulse shape is applied.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

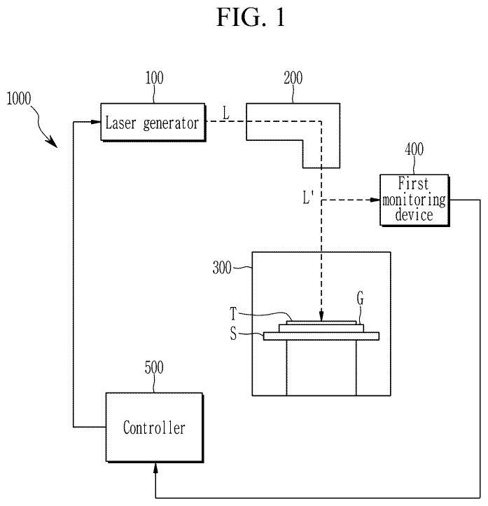

A laser crystallization apparatus according to an embodiment will be described with reference to FIG. 1. FIG. 1 is a view schematically illustrating the laser crystallization apparatus according to an embodiment.

Referring to FIG. 1, the laser crystallization apparatus 1000 according to an embodiment includes a laser generator 100 for generating an incident laser beam L, an optical system 200 for optically converting the incident laser beam L to generate an output laser beam (or an emission laser beam) L′, and a process chamber 300 in which a process of crystallizing a thin film T formed on a substrate G is performed by radiating the output laser beam.

The thin film T may be a semiconductor layer constituting a transistor in a display panel. In an embodiment, for example, the thin film may be an amorphous silicon layer, and may be crystallized by a crystallization method using an excimer laser annealing method to form a polycrystalline silicon layer.

The incident laser beam L generated from the laser generator 100 may be an excimer laser beam that induces a phase change of the thin film T. The laser generator 100 may include a plurality of laser generators that generates a plurality of laser beams. The plurality of incident laser beams L generated from the plurality of laser generators may be converted to a synthesized output laser beam L′ while passing through the optical system 200 so that the synthesized output laser beam is radiated to the process chamber 300.

In addition, the laser crystallization apparatus 1000 according to an embodiment may further include a first monitoring device 400 for monitoring a laser pulse shape of the output laser beam L′ outputted from the optical system 200 and a controller 500 that is connected to the first monitoring device to analyze the laser pulse shape and control an oscillation condition (e.g., an oscillation time) of the incident laser beam.

The optical system 200 changes an energy distribution of the incident laser beam L having an asymmetric energy distribution to allow the output laser beam L′ to have a uniform energy distribution. The optical system 200 includes a plurality of lenses and a plurality of modulators which are not shown in FIG. 1. The plurality of lenses and the plurality of modulators invert the incident laser beam L in a long axis direction and a short axis direction to convert the inverted laser beam to the output laser beam L′. In an embodiment, for example, the optical system 200 may include at least one mirror that entirely reflects the laser beam L and at least one splitter that reflects a portion of the laser beam L incident thereto and transmits another portion of the laser beam L incident thereto. In addition, the optical system 200 may include a telescope lens, a homogenizer, a cylindrical lens, or the like that are sequentially positioned.

A stage S is positioned in the process chamber 300, and the substrate G on which the thin film T is formed is seated on the stage S. Crystallization of the thin film T formed on the substrate G positioned on the stage S in the process chamber 300 is performed. The output laser beam L′ is radiated to the thin film T so that crystallization of the thin film T is performed. The thin film T may be an amorphous silicon layer, and may be formed by a method such as low pressure chemical vapor deposition (LPCVD), atmospheric pressure chemical vapor deposition (APCVD), plasma enhanced chemical vapor deposition (PECVD), sputtering, vacuum deposition, or the like.

The first monitoring device 400 may detect a shape of a laser pulse of the output laser beam L′ outputted (emitted) from the optical system 200. The output laser beam L′ outputted from the optical system 200 is radiated to the process chamber 300, and the first monitoring device 400 may receive and monitor a portion of the output laser beam L′ outputted from the optical system 200. The first monitoring device 400 may include at least one mirror that reflects a portion of the output laser beam L′ to the first monitoring device 400. In addition, the first monitoring device 400 may include at least one optical detector and a measuring instrument such as an oscilloscope to measure the shape of the laser pulse. In addition, the first monitoring device 400 may further include an attenuator for adjusting an amount of laser beam.

The first monitoring device 400 may detect an individual laser pulse shape of the incident laser beam L generated by the laser generator 100. Specifically, one incident laser beam L may be generated by only one laser generator among the plurality of laser generators. The one incident laser beam L may be outputted through the optical system 200 as an individual laser beam, and then a pulse shape of the individual laser beam may be detected. As the incident laser beam L passes through the optical system 200, light loss may occur. In an embodiment, the individual laser pulse shape of the incident laser beam L in which the light loss is reflected may be measured by detecting the pulse shape of an individual laser beam outputted through the optical system 200. Accordingly, in such an embodiment, more precise pulse management of the synthesized laser beam may be possible.

The controller 500 may predict a possible synthesized laser pulse shape by combining the measured individual laser pulse shapes of the measured incident laser beam L. The controller 500 may derive an optimal synthesized pulse shape for crystallizing the thin film T. In an embodiment, for example, a plurality of synthesized pulses may be generated by adjusting time delays of a plurality of individual laser pulses. A time delay of the individual laser pulse may be given in a unit of nanoseconds (ns). In an embodiment, for example, the individual laser beams may be combined with each other with a time delay of 50 ns.

The controller 500 may perform machine learning for deriving the optimal synthesized pulse shape. The machine learning is an algorithm technology that categorizes/learns characteristics of input data by itself, and is a method of improving performance by learning a result of a specific action. For example, the machine learning uses a machine learning algorithm such as Q-learning, Deep Q-learning, Double Deep Q-learning, a decision tree, a neural network, a support vector machine (SVM), a genetic algorithm, Bayesian optimization, or the like. For example, the Q-learning is a method of learning with a goal of finding an optimal value (or a reward) among actions that may be taken in a certain state(s), and the neural network (or a neural network method) is a method that takes an action according to a need (or a reward) by recognizing a certain state(s) using a neural network that imitates a human brain function and corresponds to a case in which an action that may be taken in a certain state is fixed so that the action may not be limited to a simple table or a human nervous system.

Algorithm elements described above may be implemented entirely or partially as software or hardware (e.g., a part of an application-specific integrated circuit (IC)) that actually operates in a specific digital signal processor, a general-purpose processor, or the like.

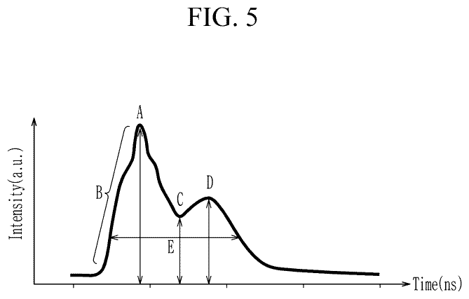

The controller 500 learns a synthesized laser pulse prediction model based on a combination of time delays of a plurality of individual laser pulses through the machine learning, and derives an optimal synthesized laser pulse. The optimal synthesized pulse shape may be derived (or determined) by applying a score method, and the score method will be described below with reference to FIG. 5.

As described above, the laser crystallization apparatus according to an embodiment may generate synthesized pulses of all possible cases using the machine learning using artificial intelligence, and may derive an optimal synthesized pulse so that more efficient and automated management of a synthesized pulse shape may be possible.

The controller 500 may derive an optimal synthesized pulse for laser crystallization, and based on the optimal synthesized pulse, may provide a time delay so that oscillation times (or oscillation timings) of the laser generators may be different from each other. That is, oscillation times of the incident laser beams L may be controlled or set to achieve a derived optimal synthesized pulse shape.

The controller 500 may include a plurality of functional modules including a module for performing the machine learning, a module for controlling the laser generator, or the like, and the plurality of functional modules may be configured as or integrated into a single module.

As described above, the laser crystallization apparatus according to an embodiment may effectively manage a quality of thin film crystallization by monitoring a synthesized laser pulse that affects the crystallization quality, managing an optimal synthesized laser pulse shape based on individual laser pulse data, and controlling the optimal synthesized laser pulse shape in real time. In particular, the laser crystallization device according to an embodiment may manage the thin film crystallization quality such as a crystal size, a crystal arrangement, mura visibility, or the like through a management of the synthesized laser pulse so that an electrical characteristic (e.g., electron mobility or the like) of a display panel to be used for a high-spec product is effectively secured.

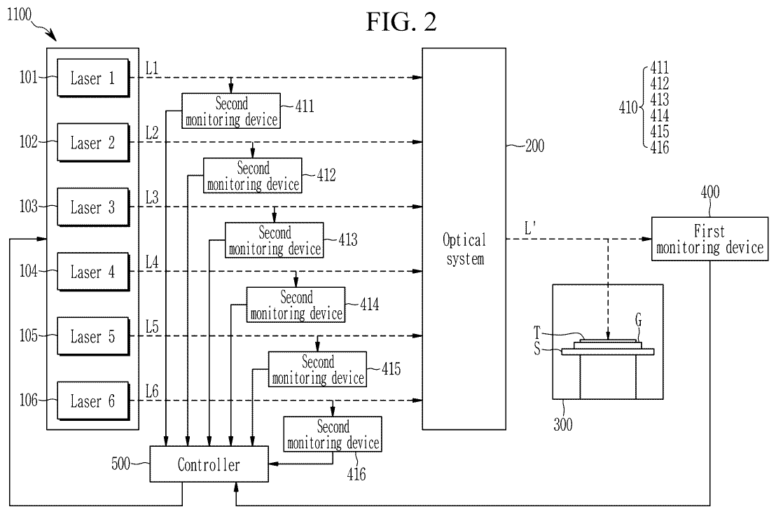

FIG. 2 is a view schematically illustrating a laser crystallization apparatus according to an embodiment.

The laser crystallization apparatus 1100 according to an embodiment may include a plurality of laser generators 101, 102, 103, 104, 105, and 106, a plurality of second monitoring devices 411, 412, 413, 414, 415, and 416 for monitoring the incident laser beams, the optical system 200 for processing the incident laser beams L1, L2, L3, L4, L5, and L6 and changing the processed beams to an output laser beam L′, the process chamber 300 in which a process of crystallizing a thin film T formed on a substrate G is performed by radiating the output laser beam L′, the first monitoring device 400 monitoring the output laser beam L′, and a controller 500 that is connected to the first monitoring device and the second monitoring devices and controls the laser generators.

The laser generators 101, 102, 103, 104, 105, and 106 may collectively define the laser generator 100 shown in FIG. 1. Although FIG. 2 shows an embodiment including six laser generators, the number of the laser generator may be two, four, five, seven, eight, ten, or the like according to an embodiment. Each of the laser generators 101, 102, 103, 104, 105, and 106 may generate an individual incident laser beam L1, L2, L3, L4, L5, or L6. The individual incident laser beam L1, L2, L3, L4, L5, or L6 may travel to the optical system 200.

An individual laser pulse of the incident laser beams L1, L2, L3, L4, L5, and L6 generated from each of the laser generators 101, 102, 103, 104, 105, and 106 may be respectively measured by the second monitoring devices 411, 412, 413, 414, 415, and 416. The second monitoring device 410 may receive and monitor a portion of each of the individual laser beams L1, L2, L3, L4, L5, and L6 generated by the laser generators. The second monitoring device 410 may include at least one mirror and at least one splitter for receiving a portion of each of the individual laser beams L1, L2, L3, L4, L5, and L6 traveling to the optical system 200. In addition, the second monitoring device 410 may include at least one optical detector and a measuring instrument such as an oscilloscope to measure a shape of a laser pulse. In addition, the second monitoring device 410 may further include an attenuator for adjusting an amount of laser beam.

The individual laser beams L1, L2, L3, L4, L5, and L6 may be converted into an output laser beam L′ having a shape of a synthesized laser beam through the optical system 200.

The synthesized laser pulse shape of the output laser beam L′ may be measured by the first monitoring device 400. The first monitoring device 400 may receive and monitor a portion of the output laser beam L′ outputted from the optical system 200. The optical system 200 may include at least one mirror and at least one splitter that reflect a portion of the output laser beam L′ to the first monitoring device 400. In addition, the first monitoring device 400 may include at least one optical detector and a measuring instrument such as an oscilloscope to measure a shape of a laser pulse. In addition, the first monitoring device 400 may further include an attenuator for adjusting an amount of laser beam.

The optical system 200 may include at least one mirror, at least one splitter, a plurality of lenses, and a plurality of modulators, and may change an energy distribution of the incident laser beams L1, L2, L3, L4, L5, and L6 to allow the synthesized emission laser beam L′ to have a uniform energy distribution.

Crystallization of the thin film T formed on the substrate G positioned on the stage S in the process chamber 300 is performed. The output laser beam L′ is radiated to the thin film T so that crystallization of the thin film T is performed.

The controller 500 may be connected to the first and second monitoring devices 400 and 410 to receive individual laser pulse shapes of the incident laser beams L1, L2, L3, L4, L5, and L6 and the synthesized laser pulse shape of the output laser beam L′ in real time.

The controller 500 may combine the individual laser pulses of the incident laser beams L1, L2, L3, L4, L5, and L6 measured by the second monitoring device 410 to predict a possible synthesized laser pulse shape, and may derive an optimal synthesized pulse shape by applying a score method. In an embodiment, for example, a plurality of synthesized pulse shapes may be generated by applying a time delay to the measured individual laser pulses. A time delay of the individual laser pulse may be given in a unit of nanoseconds (ns). In an embodiment, for example, the individual laser beams may be combined with one another with a time delay of 50 ns. The controller 500 may generate synthesized pulse shapes of all possible cases through machine learning, and may derive the optimal synthesized pulse shape among the generated synthesized pulse shapes.

The controller 500 may control an oscillation time by applying a time delay to each of the laser generators 101, 102, 103, 104, 105, and 106 to achieve the derived optimal synthesized pulse shape. The controller 500 may include a plurality of functional modules including a module for performing the machine learning, a module for controlling the laser generator, or the like, and may also be configured as or integrated into a single module.

As described above, the laser crystallization apparatus according to an embodiment may use individual pulse data obtained from each of the laser generators (or pulse lasers) so that an equipment condition (e.g., the oscillation time and the time delay of each of the laser generators (or laser oscillators) are automatically adjusted to induce the optimal synthesized pulse shape that provides the highest quality during crystallization. In such an embodiment, as described above, as equipment is controlled in advance to derive the optimal synthesized pulse shape, it is possible to manage a crystallization quality of the thin film in advance and control the crystallization quality of the thin film in real time.

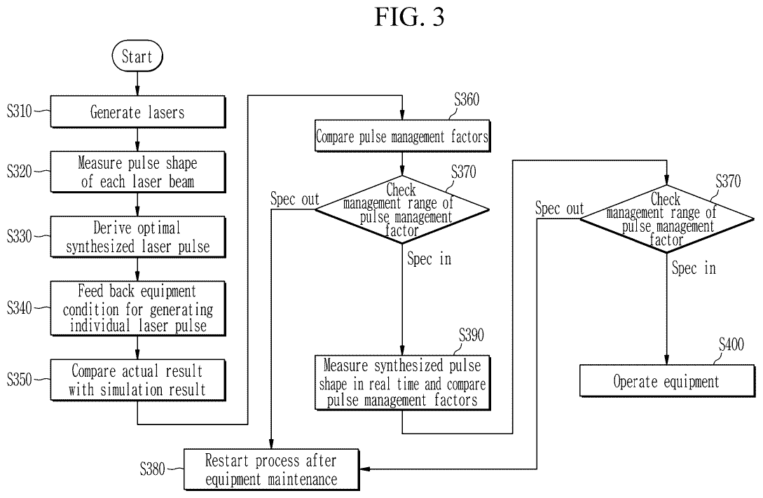

FIG. 3 is a real-time flowchart of a laser crystallization method according to an embodiment.

First, a plurality of lasers are generated (S310). Thereafter, a pulse shape of an individual laser beam is measured (S320). The individual laser beam generated by each of a plurality of laser generators may be radiated to an optical system. In this case, a portion of the laser beam may be received to measure a pulse shape of the individual laser beam in an initial state. In addition, only one laser generator among the laser generators may be operated so that the pulse shape of one individual laser beam is measured after the individual laser beam generated by one laser generator passes through the optical system. In this case, the pulse shape of the individual laser beam in which light loss occurs while the individual laser beam passes through the optical system is reflected may be measured, and thus, more precise control for deriving an optimal synthesized laser pulse may be possible.

Thereafter, a synthesized laser pulse of the measured individual laser beams may be generated and the optimal synthesized laser pulse may be derived (S330). A plurality of synthesized pulse shapes may be generated by adjusting time delays of shapes of the measured individual laser pulses. A simulation for all cases corresponding to the number of the laser generators and a time delay interval of each of the laser generators may be performed using artificial intelligence to generate the synthesized pulse shapes, and a predetermined score may be given based on a management factor extracted from the synthesized pulse to determine a shape of the optimal synthesized laser pulse. This process may be performed based on machine learning, and the optimal synthesized pulse shape may be an optimal result derived by calculating the number of hundreds of millions to billions of cases.

Thereafter, an equipment condition (e.g., an oscillation time and time delay information of each of the laser generators) based on the simulation result for generating individual laser pulses capable of achieving the optimal synthesized pulse shape is fed back to an equipment (S340). Then, a time delay is applied to each laser generator based on feedback data for the individual laser pulse to generate an actual synthesized laser pulse and compare the actual result with the simulation result (S350). A comparison between the optimal synthesized pulse shape by the simulation for synthesizing the individual laser pulses and a shape of the actual synthesized laser pulse may be calculated by comparing pulse management factors that determine the pulse shape (S360).

A pulse shape of a unit pulse laser may include a first peak, a second peak, and a valley between the first peak and the second peak. A pulse width is a duration of a pulse, may be expressed in a unit of second (sec), and may have a unit of nanosecond (ns). The pulse width is defined as a full width at half maximum (FWHM). That is, the full width at half maximum means a time width between two points that are half of the highest point.

The pulse management factor may be factors extracted from the pulse shape. In an embodiment, for example, since the pulse shape of the pulsed laser may be affected by a first peak intensity, a first peak smoothness (or a first peak smoothness up to a first peak), a second peak intensity, an intensity of the valley between the first peak and the second peak, a pulse width, and the like, the first peak intensity, the first peak smoothness, the second peak intensity, the valley intensity, the pulse width, and the like may be defined as the pulse management factor. The pulse management factor may be quantified and managed. Details regarding the pulse management factor will be described below with reference to FIGS. 5 to 8.

A quantified pulse management factor of the optimal synthesized pulse shape corresponding to the simulation result and a quantified pulse management factor of the actual synthesized pulse shape may be respectively compared (S370). In a case (spec out) in which a result of the comparison is out of a predetermined management (or manageable) range, it is possible to check whether the equipment is defective (S380). A performance change of the laser generator, whether there is an abnormality in the monitoring device, whether there is an abnormality in the optical system, or the like may be checked in the checking of whether the equipment is defective so that a process is performed again.

In a case (spec in) in which the result of comparing the quantified pulse management factors of the optimal synthesized pulse shape and the actual synthesized pulse shape is within the predetermined management range, the synthesized pulse shape may be measured in real time and the pulse management factor (or a determining factor) may be continuously measured (S390). Thereafter, the synthesized pulse shape may be continuously measured in real time, and the pulse management factor of the measured synthesized pulse shape may be compared with the pulse management factor of the simulation result, whether the equipment is defective may be checked if the result of the comparison is out of the management range (S380), and the equipment may be operated if the result of the comparison is within the management range (S400).

As described above, since the shape of the synthesized pulse laser is measured in real time and whether there is an abnormality in the equipment is checked, precise management of the synthesized laser shape is possible so that preliminary management and efficient automated management of the thin film crystallization quality are possible.

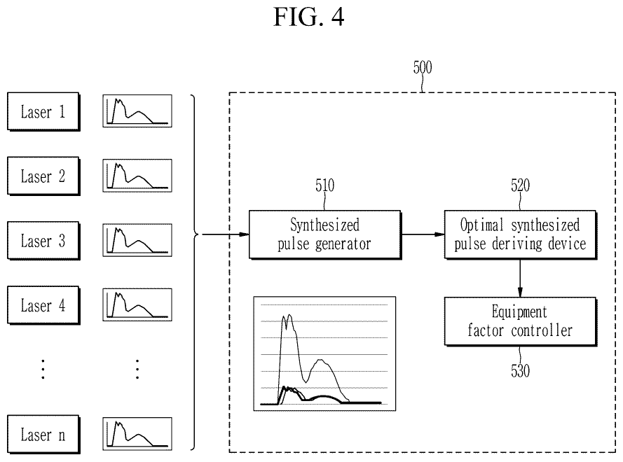

FIG. 4 is a view illustrating a configuration of the controller according to an embodiment.

According to the embodiment, the controller 500 may include a synthesized pulse generator 510, an optimal synthesized pulse deriving device 520, and an equipment factor controller 530.

The controller 500 receives individual pulse data of the plurality of laser beams. The synthesized pulse generator 510 may generate the plurality of synthesized pulses by applying a time delay to each of the received individual laser pulses. The synthesized pulse generator 510 may generate the synthesized pulses by performing a simulation for all cases combined according to the number of the individual laser pulses and the time delay of the individual laser pulse using the artificial intelligence (AI). The time delay of the individual laser pulse may be given in a unit of nanoseconds (ns). In an embodiment, for example, the individual laser pulses may be combined with a time delay of 50 nm.

The optimal synthesized pulse deriving device 520 may perform the machine learning to derive the optimal synthesized pulse shape. The machine learning is an algorithm technology that categorizes/learns characteristics of input data by itself, and is a method of improving performance by learning a result of a specific action. In an embodiment, for example, the machine learning uses a machine learning algorithm such as Q-learning, Deep Q-learning, Double Deep Q-learning, a decision tree, a neural network, a support vector machine (SVM), a genetic algorithm, Bayesian optimization, or the like.

Algorithm elements described above may be implemented entirely or partially as software or hardware (e.g., a part of an application-specific IC) that actually operates in a specific digital signal processor, a general-purpose processor, or the like.

As described above, the number of hundreds of millions to billions of cases may be calculated by applying the artificial intelligence and the machine learning so that the optimal synthesized pulse is derived. If the billions of cases are manually calculated, it may take several months to more than a year to verify the billions of cases. However, through big data analysis and the machine learning, it is possible to derive the optimal synthesized pulse shape within minutes so that crystallization quality may be managed more efficiently.

The equipment factor controller 530 may control input factors of the laser crystallization apparatus based on the individual pulse data to form the derived optimal synthesized pulse. In an embodiment, for example, a laser oscillation time may be controlled by applying the time delay to the laser generators. Each functional unit of the controller 500 according to an embodiment may include a plurality of modules or may be implemented as a single module.

FIG. 5 is a graph illustrating the synthesized pulse shape according to an embodiment. Referring to FIG. 5 and Table 1 below, a method of giving a score according to the pulse management factor will be described.

The pulse management factor may be factors extracted from the pulse shape. For example, since the pulse shape of the pulsed laser may be affected by a first peak intensity, a first peak smoothness, a second peak intensity, an intensity of the valley between the first peak and the second peak, a pulse width, and the like, the first peak intensity, the first peak smoothness, the second peak intensity, the valley intensity, the pulse width, and the like may be defined as the pulse management factor. The factors according to the pulse shape may be quantified and managed.

Items in Table 1 represent the management factor of the synthesized pulse shape, and a weight according to the thin film represents a weight of the pulse management factor given according to a degree of crystallization of the thin film. For example, the degree of crystallization of the thin film may be classified based on a surface roughness, a crystal size, a mura visibility, or the like of the crystallized thin film.

TABLE 1

| | | Weight according to thin film | | |
|---|---|---|---|---|
| | | First | Second | Third |
| | Item | thin film | thin film | thin film |
| A | First peak intensity | 0.5 | 0.35 | 0.45 |
| B | First peak smooth | 0.15 | 0.1 | 0.2 |
| C | Valley intensity | 0.1 | 0.25 | 0.1 |
| D | Second peak intensity | 0.1 | 0.2 | 0.15 |
| E | Pulse width | 0.15 | 0.1 | 0.1 |
| | (full width at half maximum) | | | |
| | Sum | 1 | 1 | 1 |

For example, in a case where the thin film is the first thin film, a first peak intensity (A) according to the weight of the pulse management factor is given as 0.5, a first peak smoothness (B) according to the weight of the pulse management factor is given as 0.15, a valley intensity (C) according to the weight of the pulse management factor is given as 0.1, a second peak intensity (D) according to the weight of the pulse management factor is given as 0.1, and a pulse width (E) according to the weight of the pulse management factor is given as 0.15. The highest value of a sum of a final score obtained by providing the weight to the quantified results (A, B, C, D, and E) of each item of the optimal synthesized pulse shape for optimal crystallization of the first thin film may be determined as the optimal synthesized pulse. In a case where the thin film is the second thin film, a first peak intensity (A) according to the weight of the pulse management factor is given as 0.35, a first peak smoothness (B) according to the weight of the pulse management factor is given as 0.1, a valley intensity (C) according to the weight of the pulse management factor is given as 0.25, a second peak intensity (D) according to the weight of the pulse management factor is given as 0.2, and a pulse width (E) according to the weight of the pulse management factor is given as 0.1. The highest value of a sum of a final score obtained by providing the weight to the quantified results (A, B, C, D, and E) of each item of the optimal synthesized pulse shape for optimal crystallization of the second thin film may be determined as the optimal synthesized pulse. In a case where the thin film is the third thin film, a first peak intensity (A) according to the weight of the pulse management factor is given as 0.45, a first peak smoothness (B) according to the weight of the pulse management factor is given as 0.2, a valley intensity (C) according to the weight of the pulse management factor is given as 0.1, a second peak intensity (D) according to the weight of the pulse management factor is given as 0.15, and a pulse width (E) according to the weight of the pulse management factor is given as 0.1. The highest value of a sum of a final score obtained by providing the weight to the quantified results (A, B, C, D, and E) of each item of the optimal synthesized pulse shape for optimal crystallization of the third thin film may be determined as the optimal synthesized pulse. A weight given to a type of the thin film may be a predetermined statistical value according to a variable of the determining factor of the pulse shape that affects the type of the thin film, and a sum of the weights for the determining factor may be 1.

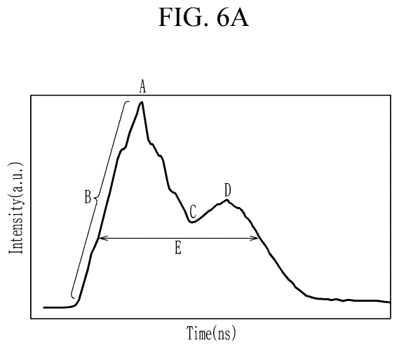

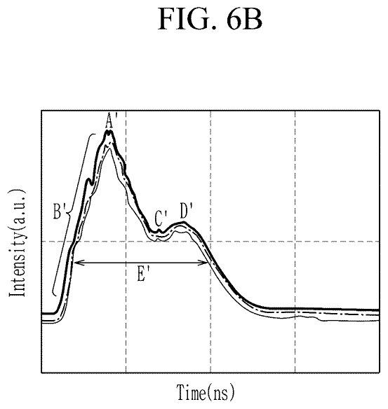

FIGS. 6A and 6B are views comparing the actual measurement result with the simulation result according to an embodiment.

FIG. 6A is the optimal synthesized pulse shape derived by the simulation using the artificial intelligence (AI), and FIG. 6B is the actually measured synthesized pulse shape of the output laser beam. By comparing the quantified pulse management factor of the synthesized pulse shape of FIG. 6A and the quantified pulse management factor of the synthesized pulse shape of FIG. 6B, it is possible to check whether the two laser pulses are substantially the same as each other or whether the difference between the two laser pulses is within the predetermined management range. In an embodiment, for example, a degree of equality between the actual measurement result and the simulation result may be checked based on one of first peak intensities A and A′, first peak smoothness B and B′, second peak intensities D and D′, valley intensities C and C′, and pulse widths E and E′. In an embodiment, as shown in FIGS. 6A and 6B, it may be determined that the actual measurement result and the simulation result have the same synthesized pulse shape within an error range. In this case, the equipment may be operated according to a condition of the simulation within the management range.

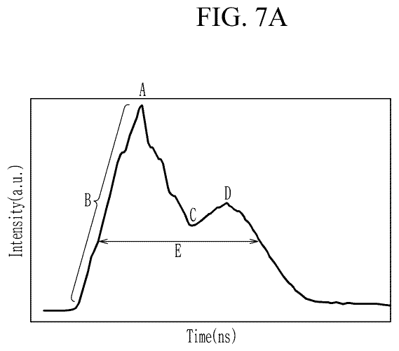

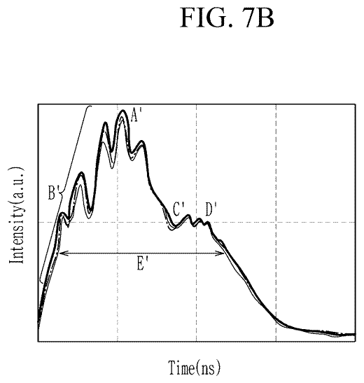

FIGS. 7A and 7B are views comparing the actual measurement result with the simulation result according to an embodiment.

FIG. 7A is the optimal synthesized pulse shape derived by the simulation using the artificial intelligence (AI) under a certain condition. FIG. 7B is the actually measured synthesized pulse shape of the output laser beam. By comparing the quantified pulse management factor of the synthesized pulse shape of FIG. 7A and the quantified pulse management factor of the synthesized pulse shape of FIG. 7B, it is possible to check whether the simulation result and the actual measurement result are substantially the same as each other or whether the difference between the simulation result and the actual measurement result is within the predetermined management range. In an embodiment, for example, a degree of equality between the actual measurement result and the simulation result may be checked based on one of first peak intensities A and A′, first peak smoothness B and B′, second peak intensities D and D′, valley intensities C and C′, and pulse widths E and E′. In an embodiment, as shown in FIGS. 7A and 7B, it is determined that a difference value between the first smoothness B and B′ up to the first peak is out of an error limit of the management range and that the actual measurement result is different from the simulation result. In this case, the result of the comparison may be determined to be out of the predetermined management range so that a real-time abnormality detection signal is generated and whether the equipment is defective is checked.

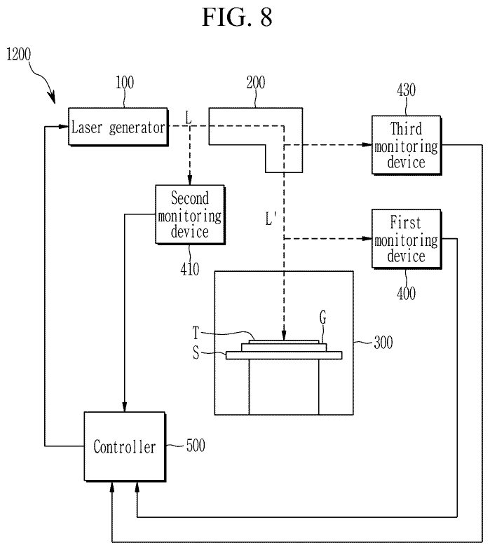

FIG. 8 is a view schematically illustrating a laser crystallization apparatus according to an embodiment.

Referring to FIG. 8, the laser crystallization apparatus 1200 according to an embodiment includes the laser generator 100 generating an incident laser beam L, the optical system 200 for processing the incident laser beam L and changing the processed beam to an output laser beam L′, and the process chamber 300 in which a process of crystallizing a thin film T formed on a substrate G is performed by radiating the output laser beam L′.

The laser generator 100 may be a device for generating the incident laser beam L, and may include a plurality of laser generators for generating a plurality of laser beams. The laser crystallization apparatus 1200 may further include the second monitoring device 410 and a third monitoring device 430 in comparison with the laser crystallization apparatus of FIG. 1.

The optical system 200 changes an energy distribution of the incident laser beam L having an asymmetric energy distribution to allow the output laser beam L′ to have a uniform energy distribution.

Crystallization of the thin film T formed on the substrate G positioned on the stage S in the process chamber 300 is performed.

The second monitoring device 410 may receive and monitor a portion of the laser beam generated by the laser generator 100. The second monitoring device 410 may measure a pulse shape of the laser beam in an initial state generated by the laser generator 100.

The third monitoring device 430 may receive and monitor a portion of the laser beam at an arbitrary point within the optical system 200. The third monitoring device 430 may be positioned inside the optical system 200 or outside the optical system 200, and may measure a pulse shape of an individual laser beam passing through the arbitrary point within the optical system 200.

The first monitoring device 400 may receive and monitor a portion of the output laser beam completely passed through the optical system 200.

The controller 500 may predict a possible synthesized laser pulse shape by combining the measured individual laser pulse shapes of the measured incident laser beam L. The controller 500 may derive an optimal synthesized pulse shape for crystallizing the thin film T.

In an embodiment, the laser crystallization apparatus 1200 may include the first, second, and third monitoring devices so that a pulse shape of the individual laser beam in an initial state, a pulse shape of the individual laser beam positioned at an arbitrary point in the optical system, and a pulse shape of the individual laser beam after a time point at which the individual laser beam completely passes through the optical system are measured. A point at which light loss occurs may be identified by comparing pulse data of the pulse shape of the individual laser beam in the initial state, pulse data of the pulse shape of the individual laser beam positioned at the arbitrary point in the optical system, and pulse data of the pulse shape of the individual laser beam after the time point, and the synthesized pulses may be generated based on the pulse shape that reflects light loss of the laser beam passing through the optical system and the optimal synthesized laser pulse may be derived so that more precise control for deriving the optimal synthesized laser pulse is possible.

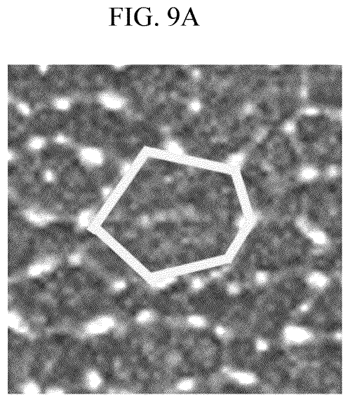

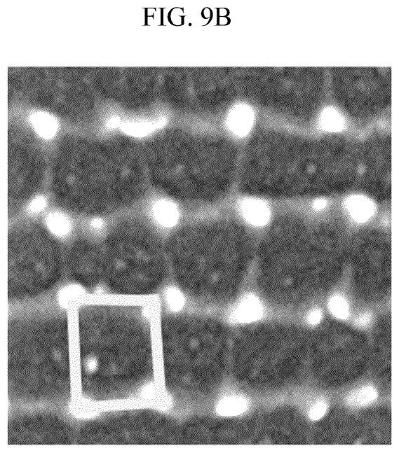

FIGS. 9A and 9B are views regarding degrees of crystallization before and after optimization control for the synthesized pulse shape is applied. FIG. 9A is a view showing a degree of crystallization before the optimization control for the synthesized pulse shape is applied, and FIG. 9B is a view showing a degree of crystallization after the optimization control for the synthesized pulse shape is applied. It may be seen that a crystal size in FIG. 9B is more uniform than that in FIG. 9A, and crystals in FIG. 9B are arranged at regular intervals so that overall uniformity is improved. Accordingly, since an electrical characteristic (e.g., electron mobility) of a display panel including the thin film formed using a synthesized laser beam having the optimized synthesized pulse shape is improved and power and data movement are facilitated, a thin film may be formed to have improved characteristics for a high-spec product.

In addition, a mura visibility, which is difficult to check with the naked eye, may be improved through optimized management of the synthesized pulse according to an embodiment. For example, the mura visibility is data obtained by quantifying a mura level of a semi-finished product, and as a value of the mura visibility is higher, a risk of a spot defect may be higher. The value of the mura visibility may increase as crystallization uniformity of a polycrystalline silicon layer decreases. A degree of the mura visibility may be numerically expressed, and when the optimization control for the synthesized pulse shape is applied as shown in FIG. 9B, the crystallization uniformity of the polycrystalline silicon layer may be improved so that the mura visibility is low. Therefore, according to an embodiment, a defect may be effectively and efficiently predicted, and it is possible to prevent a crystallization defect, which is difficult to check by visual inspection, in advance.

The optimal synthesized pulse is derived through input management of the laser pulse that is a major factor in thin film crystallization so that it is possible to improve a defect rate due to abnormal crystallization, which is difficult to visually inspect, through prior detection.

The invention should not be construed as being limited to the embodiments set forth herein. Rather, these embodiments are provided so that this disclosure will be thorough and complete and will fully convey the concept of the invention to those skilled in the art

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A laser crystallization apparatus comprising:
a plurality of laser generators which generates an incident laser beam;
an optical system which optically converts the incident laser beam to an output laser beam;
a process chamber in which a thin film formed on a substrate is crystallized by the output laser beam radiated thereto;
a first monitoring device which detects a synthesized pulse of the output laser beam;
a second monitoring device which detects individual pulses of the incident laser beam; and
a controller which controls oscillation times of the plurality of laser generators,
wherein the controller generates a plurality of synthesized pulses by combining the individual pulses of the incident laser beam, and derives an optimal synthesized pulse from the plurality of synthesized pulses.

2. The laser crystallization apparatus of claim 1, wherein the controller controls the oscillation times of the plurality of laser generators in a way such that the synthesized pulse of the output laser beam is substantially the same as the optimal synthesized pulse.

3. The laser crystallization apparatus of claim 1, wherein
the controller generates each of the plurality of synthesized pulses by applying a time delay to each of the individual pulses.

4. The laser crystallization apparatus of claim 1, wherein
the oscillation times of the plurality of laser generators are determined based on time delays of the individual pulses constituting the optimal synthesized pulse.

5. The laser crystallization apparatus of claim 1, wherein
the optimal synthesized pulse is derived by calculating a score based on a pulse management factor extracted from the synthesized pulses.

6. The laser crystallization apparatus of claim 5, wherein
a weight according to a degree of crystallization of the thin film is given to the pulse management factor to calculate the score.

7. The laser crystallization apparatus of claim 6, wherein
the degree of crystallization of the thin film is determined based on at least one selected from a surface roughness, a crystal size, and mura visibility of the thin film.

8. The laser crystallization apparatus of claim 1, wherein
the controller compares a pulse management factor of the synthesized pulse of the output laser beam with a pulse management factor of the optimal synthesized pulse, and generates an abnormality detection signal when a comparison result is out of a predetermined range.

9. The laser crystallization apparatus of claim 1, wherein
the controller generates a synthesized pulse of the incident laser beam and derives the optimal synthesized pulse through a machine learning.

10. The laser crystallization apparatus of claim 9, wherein
the machine learning uses at least one selected from Q-learning, Deep Q-learning, Double Deep Q-learning, a decision tree, a neural network, a support vector machine (SVM), a genetic algorithm, and Bayesian optimization.

11. The laser crystallization apparatus of claim 1, further comprising
a third monitoring device which detects shapes of the individual pulses of the incident laser beam at an arbitrary point within the optical system.

12. A laser crystallization apparatus comprising:
a plurality of laser generators which generates a plurality of individual laser beams;
an optical system which optically converts the individual laser beams to a synthesized laser beam;
a process chamber in which a thin film formed on a substrate is crystallized by the synthesized laser beam radiated thereto;
a first monitoring device which detects a pulse of each of the individual laser beams and a pulse of the synthesized laser beam; and
a controller which controls oscillation times of the plurality of laser generators,
wherein the controller derives an optimal synthesized pulse among a plurality of synthesized pulses obtained by combining pulses of the individual laser beams detected by the first monitoring device.

13. The laser crystallization apparatus of claim 12, wherein
the controller controls the oscillation times of the plurality of laser generators in a way such that the pulse of the synthesized laser beam is substantially the same as the optimal synthesized pulse.

14. The laser crystallization apparatus of claim 12, wherein
the first monitoring device detects a pulse of an individual laser beam output from one of the plurality of laser generators through the optical system.

15. The laser crystallization apparatus of claim 12, wherein
the controller compares a pulse management factor of the pulse of the synthesized laser beam with a pulse management factor of the optimal synthesized pulse, and generates an abnormality detection signal when a comparison result is out of a predetermined range.

16. A laser crystallization method, in which a synthesized laser beam obtained by optically converting a plurality of laser beams is radiated to crystallize a thin film, the laser crystallization comprising:
generating a plurality of laser beams from a plurality of laser generators;
monitoring individual pulses of the plurality of laser beams;
generating a plurality of synthesized pulses by applying a time delay to each of the individual pulses;
deriving an optimal synthesized pulse from the plurality of synthesized pulses; and
comparing the optimal synthesized pulse with a pulse of the synthesized laser beam.

17. The laser crystallization method of claim 16, wherein
the monitoring the individual pulses of the plurality of laser beams comprises monitoring an individual pulse of a laser beam after the laser beam generated by only one laser generator among the plurality of laser generators passes through an optical system.

18. The laser crystallization method of claim 16, wherein
the deriving the optimal synthesized pulse comprises deriving the optimal synthesized pulse based on at least one selected from a first peak intensity, a first peak smoothness up to a first peak, a second peak intensity, an intensity of a valley between the first peak and a second peak, and a full width at half maximum which is a time width at a half height of the first peak,
wherein the first peak intensity, the first peak smoothness, the second peak intensity, the intensity of the valley, and the full width at half maximum are included in a pulse management factor.

19. The laser crystallization method of claim 16, further comprising
generating an abnormality detection signal when a result of comparing the optimal synthesized pulse with the pulse of the synthesized laser beam is out of a predetermined range.

20. The laser crystallization method of claim 16, further comprising
controlling oscillation times of the plurality of laser generators based on time delays of the individual pulses constituting the optimal synthesized pulse.
